(19) United States
(12) Patent Application Publication
(10) Pub. No.: US 2017/0110390 A1
(43) Pub. Date: Apr. 20, 2017

(54) SUPPORT AND/OR CLIP FOR SEMICONDUCTOR ELEMENTS, SEMICONDUCTOR COMPONENT, AND PRODUCTION METHOD

(71) Applicant: HERAEUS DEUTSCHLAND GMBH & CO. KG, Hanau (DE)

(72) Inventors: Andreas HINRICH, Freigericht (DE); Reinhard DITZEL, Linsengericht (DE); Andreas KLEIN, Freigericht (DE)

(73) Assignee: HERAEUS DEUTSCHLAND GMBH & CO. KG, Hanau (DE)

(21) Appl. No.: 15/129,202

(22) PCT Filed: Mar. 26, 2015
(86) PCT No.: PCT/EP2015/056599

§ 371 Date: Sep. 26, 2016

(30) Foreign Application Priority Data
Mar. 26, 2014 (DE) 10 2014 104 267.0
Apr. 4, 2014 (DE) 10 2014 104 819.9

(51) Int. Cl. H01L 23/495; H01L 21/48; H01L 23/00; H05K 3/34

(52) U.S. Cl. CPC H01L 23/49548; H05K 3/3452; H01L 23/49503; H01L 21/4842; H01L 21/4828; H01L 24/32; H01L 24/83; H05K 2203/107; H01L 2224/32245; H01L 2224/83801; H01L 2924/17151; H01L 2924/13091

(57) ABSTRACT

The invention relates to a support and/or clip for at least one semiconductor element with at least one functional surface (10) for connecting to the semiconductor element. The invention is further characterized by at least one solder resist cavity (12) with at least one flank wall (13), in particular a straight flank wall (13), and a delimiting edge (14) which adjoins the flank wall (13) and delimits the functional surface (10) at least on one side. The delimiting edge (14) forms a protrusion (15) which protrudes past the functional surface (10) in order to retain solder, and/or the flank wall (13) forms an undercut (16) for retaining solder at the delimiting edge (14).

### BACKGROUND OF THE INVENTION

1. Field of the Invention

The invention relates to a support and/or a clip for at least one semiconductor element with at least one functional surface for connecting to the semiconductor element. A support of the aforementioned type is known for example from U.S. Pat. No. 6,577,012 B1.

2. Discussion of the Related Art

The support, also referred to as a lead frame, is a solderable metal system support in the form of a frame for producing semiconductor components or other electronic components. The support has one or more functional surfaces, which are provided for contacting and connecting to the semiconductor element. The semiconductor element is connected to the support on the functional surface by soldering. The semiconductor element is connected to the connections of the support either by bond wires or by one or more clips. Clip technology is particularly suitable for use in power electronics in conjunction with MOSFETs.

For connection of the semiconductor element to the support or lead frame, the document U.S. Pat. No. 6,577,012 B1 mentioned at the outset suggests providing a plurality of solder points between the semiconductor element and the support. In order to prevent the liquid solder from running in an uncontrolled manner between the support and the semiconductor element, areas which can be wetted with solder are provided on the lead frame. The wettable areas are delimited by non-wettable areas, which hold back the solder at the points intended therefor. The non-wettable areas are either produced by oxidizing the surface of the support in this region by processing using a laser, whereby the wettability with solder is reduced. Alternatively, regions which cannot be wetted as well as the adjacent untreated regions are exposed from a multi-layered laminate on the support. By way of example, the non-wettable regions, which are exposed separately, are formed from a middle layer.

The lead frames thus produced do not offer sufficient security against the solder running in an uncontrolled manner, in particular when the surface is oxidized merely using a laser. The second possibility of selective exposure of non-wettable layers is complex.

### SUMMARY OF THE INVENTION

One object of the invention is to specify a support or a clip for at least one semiconductor element which, in each case, can be easily produced and provides a good retaining function for the solder in the region of the functional surface. A further object of the invention is to specify a semiconductor component and a method for producing a support or clip.

The invention is based on the concept of specifying a support and/or a clip for at least one semiconductor element with at least one functional surface for connecting to the semiconductor element. Within the scope of the invention, a support with at least one functional surface for connecting to the semiconductor element and, separately herefrom, a clip with at least one functional surface for connecting to the semiconductor element are thus disclosed and claimed. In addition, the arrangement comprising a support and a clip is disclosed and claimed, wherein the support and the clip each have a functional surface for connecting to the semiconductor element.

The support or the clip in each case has at least one solder resist cavity with at least one flank wall, in particular a straight flank wall. The flank wall is adjoined by a delimiting edge, which delimits the functional surface at least on one side.

For the retaining function, the following two features of the support or the clip are disclosed and, considered individually, each achieve the sought effect of holding back the solder at defined points. It is also possible to combine both features with one another.

The delimiting edge forms a protrusion which protrudes past the functional surface in order to hold back solder. The protrusion forms a mechanical barrier which prevents the solder from running in an uncontrolled manner. The protrusion has the advantage of simple production, for example by a forming method such as embossing or stamping or milling. In addition, the retaining effect of the protrusion is independent of the solder composition and therefore independent of the surface tension of the solder.

Alternatively or additionally to the protrusion, the flank wall forms an undercut for holding back solder at the delimiting edge. It has been found that the formation of the undercut effectively prevents solder from flowing into the solder resist cavity. The additional formation of a protrusion at the delimiting edge of the undercut further increases the security against an uncontrolled flow of solder.

The above-explained embodiment of the solder resist cavity in the region of the delimiting edge is disclosed and claimed both in conjunction with the support or the lead frame and the clip.

In a preferred embodiment, the depth of the solder resist cavity is from 10% to 80%, in particular from 30% to 50% of the thickness of the support or the thickness of the clip. The depth of the solder resist cavity specifically can be from 0.03 mm to 3 mm, in particular from 0.1 mm to 0.5 mm. The thicker the support material or the clip material is, the lower the percentage value of the solder resist cavity. The deeper the solder resist cavity is, the more effectively this can serve as a reservoir for solder which overcomes the solder resist barrier in spite of the formation of the delimiting edge with the protrusion and/or the formation of the flank wall as an undercut. A second means for securing against the undesirable spreading of the liquid solder is thus created.

The width of the solder resist cavity can be from 0.05 mm to 2 mm, in particular from 0.3 mm to 1.2 mm. Here as well, it is true that with increasing width, a greater volume serving as second security barrier is provided.

The height of the protrusion can be from 5% to 80% of the thickness of the support or the thickness of the clip, in particular from 10% to 30% of the thickness of the support or the thickness of the clip. The taller the protrusion is, the more effective the security that the solder will be held back at the points intended for this purpose in the region of the functional surface.

The solder resist cavity can have a trapezoidal cross section, wherein the longer base side of the trapezoidal cross section forms the opening. This means that the solder resist cavity tapers into the material. Alternatively, the solder resist cavity can have a wedge-shaped cross section. The wedge-shaped cross section is also open to the upper side of the support or clip. The aforementioned cross sections of the solder resist cavity can be easily produced by an embossing method. In conjunction with the specified cross sections, a protrusion in the form of a bead is formed at the delimiting edge by the embossing method by the material displaced during the embossing. The height and shape of the bead can be determined depending on the embossing depth and width of the embossment and in dependence of the cross section.

Other cross-sectional shapes which lead to the formation of a bead are possible.

In a further preferred embodiment a plurality of solder resist cavities, in particular 2 to 10 solder resist cavities, are arranged side by side in parallel on the same side of the functional surface, wherein the delimiting edge is formed at the first solder resist cavity and directly borders the functional surface. The multiple arrangement of the solder resist cavities increases the security against undesired flow of the solder because the solder resist cavities downstream of the first delimiting edge form further delimiting edges which will each have to be overcome by the solder in order for the solder to flow out over the region of the functional surface.

If the functional surface is arranged at the edge of the support, a single solder resist cavity on the side of the functional surface opposite the edge can be sufficient. A number of solder resist cavities can also be arranged on different, in particular opposite sides of the functional surface so that the retaining function acts in different directions of the support or clip.

In a particularly preferred embodiment, an acute angle between a reference plane perpendicular to the support or clip and the flank wall of the undercut is from 5° to 45°, in particular from 10° to 30°. It has been found that an improvement of the retaining function of the solder resist cavity is achieved in these angular ranges.

The delimiting edge of the flank wall of the undercut can form a bead-free, sharp edge. The sharp edge improves the effect of the surface tension and therefore the retaining function of the solder resist cavity.

Alternatively, the delimiting edge of the flank wall of the undercut can form a protrusion. In this case the solder is held back mechanically by the protrusion.

In a particularly preferred embodiment the solder resist cavity is embossed or stamped. The solder resist cavity with the bead formed at the delimiting edge as one possibility for the protrusion can be produced easily and, accordingly, economically. Furthermore, the solder resist cavity can be laser-cut or milled.

A semiconductor component with a support and/or clip and with at least one semiconductor element is also disclosed and claimed and is arranged on the functional surface of the support or clip and is connected to the support and/or clip. An edge of the semiconductor element lies against the delimiting edge of the solder resist cavity. Alternatively, the edge of the semiconductor element can be arranged at a distance from the solder resist cavity. This means that the edge of the semiconductor element does not protrude past the delimiting edge of the solder resist cavity. The semiconductor element does not overlap the solder resist cavity. It is therefore ensured in a reliable manner that no solder passes along the underside of the semiconductor element via the delimiting edge and can flow undesirably into the solder resist cavity.

In the method for producing a support and/or clip for at least one semiconductor element, provision is made for the support and/or clip to be structured, in particular structured by stamping, wherein a functional surface for connecting to the semiconductor element is formed.

Here, at least one solder resist cavity with a delimiting edge at least on one side of the functional surface is embossed or stamped into the support or into the clip using a punch. During the embossing or stamping, the punch forms a protrusion at the delimiting edge from the material of the support or the material of the clip. The protrusion in the form of a bead is formed by displacement of the material in the region of the delimiting edge during the forming process.

Here, within the scope of the invention, it is necessary that the protrusion or bead at the delimiting edge is retained and is not removed in the production process, for example is not etched away or ground down.

Alternatively or additionally, at least one solder resist cavity with a flank wall is cut at least on one side of the functional surface using a laser beam or is embossed or stamped into the support or the clip using a punch. The cutting angle of the laser beam or the plunging angle of the punch is set in such a way that the flank wall forms an undercut. If the method is performed suitably, a sharp-edged undercut can be produced both by the laser beam and by the punch, which undercut improves the retaining function by the surface tension of the solder. The sharp-edged undercut by embossing is produced in that a holding-down means rests on the support or clip in the region of the delimiting edge and prevents the bead formation, such that the transition from the inclined flank of the solder resist cavity to the upper side of the support or clip is sharp-edged. It is also possible, if desired, to produce the undercut with a rounded transition.

Alternatively or additionally, the solder resist cavity can be milled into the support and/or clip.

After the embossing or stamping or milling of the solder resist cavity using the punch, in order to form the protrusion at the delimiting edge, a forming cavity is preferably embossed or stamped into the support or into the clip next to the delimiting edge. The forming cavity displaces the delimiting edge and a flank wall of the solder resist cavity extending from the delimiting edge in order to form the undercut. Alternatively, a perpendicular solder resist cavity (i.e. without undercut) can be cut into the support and/or clip by means of a laser before the forming cavity is provided.

The method for forming the solder resist cavity is particularly well suited in conjunction with a stamping method for the production of the support or clip, for example according to DE 10 2011 010 984 B4. In the case of the stamping method, a laminate is produced from at least two films, wherein at least a first film is structured and then laminated with at least a second film. The core of the method lies in the fact that at least the second film is stamped using at least one tool in a single process step

and at the same time is laminated with the structured first film, wherein the films are conveyed at least intermittently to the at least one tool.

Additionally or alternatively to the lamination, the surface of the support or clip can be embossed or stamped or milled in order to produce the solder resist cavity.

Both the stamping of the support per se and the modification of the surface of the support are therefore carried out using the same tool, which can perform both steps, i.e. the stamping of the support and the embossing of the surface of the support. The same is true for the clip.

### BRIEF DESCRIPTION OF THE DRAWINGS

The invention will be explained in greater detail hereinafter on the basis of exemplary embodiments with further details with reference to the accompanying schematic drawings, in which:

FIG. 1a shows a plan view of a support in accordance with an exemplary embodiment according to the invention with a trapezoidal solder resist cavity;

FIG. 1b shows a side view of the support according to FIG. 1a;

FIG. 2a shows a plan view of a support in accordance with an exemplary embodiment according to the invention with a wedge-shaped solder resist cavity;

FIG. 2b shows a side view of the support according to FIG. 2a;

FIG. 3 shows a detailed view of the protrusion at the delimiting edge of the solder resist cavity;

FIG. 4a shows a variant of the support according to FIG. 2a, in which a plurality of solder resist cavities are provided;

FIG. 4b shows a side view of the support according to FIG. 4a;

FIG. 5a shows step 1 of the production of the undercut of the solder resist cavity;

FIG. 5b shows step 2 of the production of the undercut of the solder resist cavity; and

FIG. 6 shows an alternative method of producing the undercut of the solder resist cavity.

### DETAILED DESCRIPTION OF THE INVENTION

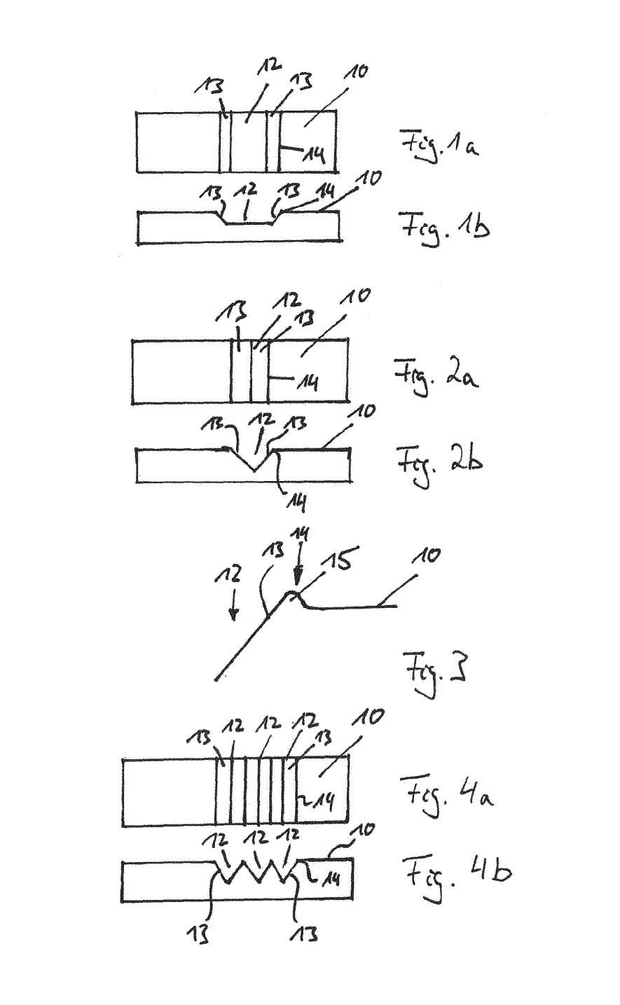

FIGS. 1a and 1b show a support, i.e. a lead frame for a semiconductor element, which has a functional surface 10 (on the right-hand side in FIGS. 1a and 1b), which is intended for connecting to a semiconductor element. The functional surface is connected to the semiconductor element by soldering. The surface of the semiconductor element is the same size as the functional surface 10 or slightly smaller. The semiconductor element is thus prevented from protruding past the functional surface 10 into the region of the solder resist cavity 12. The solder resist cavity 12 delimits the functional surface 10 and forms an effective barrier against the undesirable flow of the liquid solder.

For this purpose, the solder resist cavity 12 has a straight flank wall 13, specifically two straight flank walls 13, which are each inclined. The cross section of the solder resist cavity is trapezoidal, wherein the longer base line of the trapezoidal solder resist cavity 12 forms the opening thereof. In other words, the solder resist cavity 12 tapers. The transition from the right-hand flank 13 in FIGS. 1a and 1b to the functional surface 10 is formed by the delimiting edge 14, which adjoins the flank wall 13 and delimits the functional surface 10 on one side.

The objective of the cavity is primarily to form the delimiting edge 14 during production of the cavity so that said delimiting edge acts as a barrier for the solder. This does not rule out the fact that the cavity acts as a second barrier for the solder and can fill with solder in part. However, a situation in which the solder overcomes the delimiting edge 14 is to be avoided.

A variant of the solder resist cavity 12 is illustrated in FIGS. 2a and 2b, in which the cavity 12 has a wedge-shaped cross section. This cross section also has two inclined flanks, which taper to a point in the base of the cavity 12, as can be clearly seen in FIG. 2b. The delimiting edge 14 at the flank wall 13 shown on the right-hand side in FIG. 2b at the same time delimits the functional surface 10 on one side.

The retaining function of the delimiting edge 14 is achieved by a protrusion, specifically by a bead 15, which is raised on the delimiting edge 14 by the embossing of the solder resist cavity 12. As can be clearly seen in FIG. 3, the bead 15 or generally the protrusion 15 protrudes past the functional surface 10 and thus forms a barrier, which effectively holds back the solder in the region of the functional surface 10. The height of the barrier or bead 15 is determined by the forming process. The more material that is displaced during the embossing, the higher the bead 15 or the protrusion. The bead 15 is not removed in exemplary embodiments 1-2, but is an important feature of the final support or lead frame.

All the features according to FIGS. 1a, 1b and 2a, 2b are also disclosed and claimed in conjunction with a clip for a semiconductor element.

The clip, similarly to the bonding wires, serves to electrically connect the semiconductor element in a suitable manner. The semiconductor element and the clip are connected by soldering, as is also the case with the support. The solder resist disclosed and described in conjunction with the support is therefore also disclosed and described in conjunction with the clip.

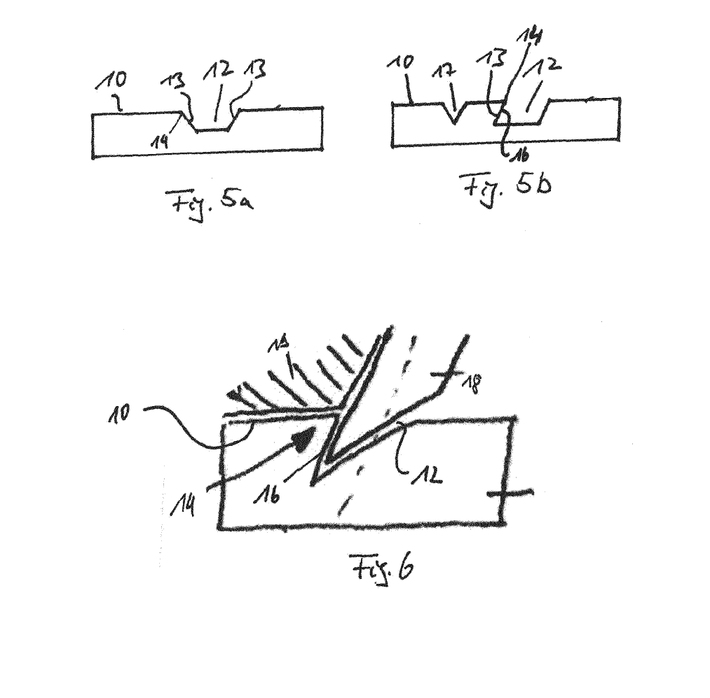

A variant of the solder resist cavity according to FIGS. 2a, 2b is illustrated in FIGS. 4a and 4b. The difference from FIG. 2a lies in the fact that in FIG. 2a a single solder resist cavity 12 is provided, which delimits the functional region 10, whereas in FIGS. 4a and 4b a number of wedge-shaped solder resist cavities 12 are provided on the same side of the functional region 10 and border one another in a sawtooth-shaped manner. The security against undesirable flow of the solder is thus further increased.

A further possibility of the solder resist cavity 12 is illustrated in FIGS. 5a and 5b. Here, an undercut 16 is formed in the support or in the clip. An undercut is understood to mean a depth profile which has an upper edge, i.e. the delimiting edge 14, which in relation to a vertical plane protrudes further than a lower edge, specifically the edge at the transition to the base of the cavity 12. In other words, the inclined flank 13 at the delimiting edge 14 protrudes back and shadows the region of the solder resist cavity 12 directly below the delimiting edge 14. A sharp-edged transition from the functional surface 10 to the inclined flank wall 13 adjacent to the functional surface 10 can thus be formed, as illustrated in the example according to FIG. 6.

Alternatively, as is made possible by the method steps according to FIGS. 5a and 5b, a bead can be formed at the delimiting edge 14 of the undercut 16. For this purpose, a solder resist cavity 16 having a trapezoidal cross section (see also FIGS. 1a and 1b) is impressed in the support in the first step according to FIG. 5a. In so doing, the bead shown in FIG. 3 is formed at the delimiting edge 14 toward the functional surface 10. In the second step according to FIG. 5b, a forming cavity 17 is made in the support close to the delimiting edge 14. The forming cavity 17 displaces the material between the forming cavity and the delimiting edge 14 of the solder resist cavity 12. This results in a movement of the delimiting edge 14 inclusive of the inclined flank wall adjoining the delimiting edge 14, such that said flank wall is urged inwardly into the solder resist cavity 16. The originally outwardly inclined flank wall 13 (see FIG. 5a) is shifted back by the urging effect of the forming cavity 17 and is inclined, as can be seen in FIG. 5b, inwardly into the solder resist cavity 12. The above-explained undercut is thus formed.

An alternative possibility for producing the undercut is shown in FIG. 6. An inclined punch 18 is used for this purpose, which plunges into the support at an angle in relation to the surface thereof. The acute punch 18 impresses the desired solder resist cavity 12 into the material of the support or the clip, forming the undercut 16 in the region of the tip of the punch. In this exemplary embodiment a particularly sharp delimiting edge 14 is formed. This is adjacent to the holding-down means 19, which prevents material from being raised in the region of the delimiting edge 14.

The above-explained method has the advantage that it can be combined easily and quickly with a stamping method for producing the support. For this purpose, the tools provided for the stamping can be converted so that, in a 2-step method, they first punch out the support and then in the next step form the desired embossing structure in the surface in order to form the solder resist or the solder resist cavity.

### LIST OF REFERENCE SIGNS

10 functional surface

12 solder resist cavity

13 flank wall

14 delimiting edge

15 protrusion/bead

16 undercut

17 forming cavity

18 punch

19 holding-down means

1. A support for a semiconductor element, the support comprising:
a functional surface for connecting to the semiconductor element;
at least one solder resist cavity comprising a flank wall and a delimiting edge, the delimiting edge adjoining the flank wall and delimiting the functional surface on a first edge of the functional surface;
wherein the delimiting edge forms a protrusion, the protrusion protruding past the functional surface for holding back solder, or
wherein the flank wall comprises an undercut for holding back solder at the delimiting edge.

2. The support as claimed in claim 1, wherein a depth of the at least one solder resist cavity ranges from 10% to 80% of a thickness of the support.

3. The support as claimed in claim 1, wherein a width of the at least one solder resist cavity ranges from 0.05 mm to 2 mm.

4. The support as claimed in claim 1, wherein a height of the protrusion ranges from 5% to 80% of a thickness of the support.

5. The support as claimed in claim 1,
wherein the at least one solder resist cavity comprises a first base side and a second base side, the second base side being longer than the first base side, and
wherein the first solder resist cavity comprises a trapezoidal cross section,
wherein the second base side is an opening of the trapezoidal cross-section.

6. The support as claimed in claim 1,
wherein the at least one solder resist cavity is a plurality of solder resist cavities,
wherein a first solder resist cavity is arranged side-by-side in parallel to a second solder resist cavity on a same side of the functional surface.
wherein the delimiting edge is formed at the first solder resist cavity, the solder resist cavity directly bordering the functional surface.

7. The support as claimed in claim 1,
wherein the at least one solder resist cavity is a plurality of solder resist cavities,
wherein a first solder resist cavity is arranged on opposite side of the functional surface to a second solder resist cavity,
wherein the delimiting edge is formed at the first solder resist cavity, the solder resist cavity directly bordering the functional surface.

8. The support as claimed in claim 1, wherein an acute angle between a reference plane perpendicular to the support and the flank wall of the undercut ranges from 5° to 45°.

9. The support as claimed in claim 1, wherein the delimiting edge of the flank wall of the undercut forms a bead-free, sharp edge.

10. The support as claimed in claim 1, wherein the delimiting edge of the flank wall of the undercut forms the protrusion.

11. The support as claimed in claim 1, wherein at least one solder resist cavity is embossed or stamped or laser-cut or milled.

12. In combination, a semiconductor component and a support, the combination comprising:
the semiconductor component comprising a device edge, and
the support comprising
a functional surface for connecting to the semiconductor element;
at least one solder resist cavity comprising a flank wall and a delimiting edge, the delimiting edge adjoining the flank wall and delimiting the functional surface on a first edge of the functional surface;
wherein the delimiting edge forms a protrusion, the protrusion protruding past the functional surface for holding back solder, or
wherein the flank wall comprises an undercut for holding back solder at the delimiting edge.
wherein the device edge of the semiconductor element lies against the delimiting edge of the at least one solder resist cavity or wherein the device edge of the semiconductor element is arranged at a distance from the at least one solder resist cavity.

13. A method of making a support for a semiconductor element the support being structured, the method comprising the steps of:
stamping the support to having a functional surface for connecting to the semiconductor element;
using a punch, embossing or stamping into at least one side of the support at least one solder resist cavity with a delimiting edge, the punch forming a protrusion at the delimiting edge from the material of the support, or
using a laser cutter, cutting at least on one side of the functional surface at least one solder resist cavity with a flank wall, wherein the laser cutter is angled to form an undercut at the flank wall, or
using a punch, embossing or stamping into the support at least on one side of the functional surface at least one solder resist cavity with a flank wall, a plunging angle of the punch being set in such a way that the flank wall forms an undercut, or
milling at least one solder resist cavity into the support.

14. The method as claimed in claim 13, wherein after embossing or stamping or milling of the solder resist cavity using the punch, the protrusion is formed at the delimiting edge, a forming cavity is embossed or stamped into the support next to the delimiting edge and displaces the delimiting edge and a flank wall of the solder resist cavity extending from the delimiting edge to form the undercut.

15. The support as claimed in claim 1, wherein the flank wall is planar.

16. The support as claimed in claim 1, wherein a depth of the at least one solder resist cavity is from 30% to 50% of a thickness of the support.

17. The support as claimed in claim 1, wherein a width of the solder resist cavity ranges from 0.3 mm to 1.2 mm.

18. The support as claimed in claim 1, wherein a height of the protrusion ranges from 10% to 30% of the thickness of the support.

19. The support as claimed in claim 1, wherein the at least one solder resist cavity a wedge-shaped cross section.

20. The support as claimed in claim 1, wherein an acute angle between a reference plane perpendicular to the support and the flank wall of the undercut ranges from 10° to 30°.
